(19) United States
(12) Patent Application Publication
(10) Pub. No.: US 2026/0096312 A1
(43) Pub. Date: Apr. 2, 2026

(54) DISPLAY DEVICE, ELECTRONIC DEVICE INCLUDING THE DISPLAY DEVICE, AND METHOD OF MANUFACTURING THE DISPLAY DEVICE

(71) Applicant: SAMSUNG DISPLAY CO., LTD., YONGIN-SI (KR)

(72) Inventor: MYONG-SOO OH, YONGIN-SI (KR)

(21) Appl. No.: 19/081,192

(22) Filed: Mar. 17, 2025

(30) Foreign Application Priority Data
Sep. 30, 2024 (KR) 10-2024-0132551

(51) Int. Cl. H10K 59/131; H10K 59/12

(52) U.S. Cl. CPC H10K 59/131; H10K 59/1201

(57) ABSTRACT

A display device includes a display panel. The display panel includes a display area including a plurality of pixels and a non-display area including a panel pad group. The panel pad group includes a plurality of panel pads arranged in a first direction and connected to one of the pixels. The panel pad group further includes an additional pad portion arranged in a lengthwise direction of each of the plurality of panel pads and spaced apart from the panel pads. The additional pad portion includes a first additional pad and a second additional pad that are sequentially spaced apart from one another in the lengthwise direction of the panel pads.

### CROSS-REFERENCE TO RELATED APPLICATION

This U.S. patent application claims priority under 35 U.S. C. § 119 to Korean Patent Application No. 10-2024-0132551, filed on Sep. 30, 2024, in the Korean Intellectual Property Office, the disclosure of which is incorporated by reference in its entirety herein.

### 1. TECHNICAL FIELD

Embodiments are directed to a display device, an electronic device including the display device, and a method of manufacturing the display device.

### 2. DISCUSSION OF RELATED ART

Flat panel display devices are key components in modern electronic devices, featuring slim profiles and lower power consumption compared to traditional CRT displays. Common types include Liquid Crystal Displays (LCDs), which utilize liquid crystals and a backlight to produce images, and Organic Light Emitting Diode (OLED) displays, known for their superior contrast and ability to produce true blacks since each pixel emits its own light. Another variation, Light Emitting Diode (LED) displays, are essentially LCDs with LED backlighting, providing brighter displays and better color accuracy. Additionally, newer technologies like Quantum Dot LED (QLED) displays enhance viewing experiences by using quantum dots to increase vibrancy and color range. These flat panel displays are used in various applications, from smartphones and tablets to large-scale televisions, due to their versatility and efficiency.

The display devices may include a display panel configured to generate an image that is controlled by a main circuit board and connected to the main circuit board via a connection circuit board. The connection circuit board may exchange electrical signals between the display panel and the main circuit board.

Pads provided on the connection circuit board and pads provided on the display panel may be bonded to each other. However, it can be challenging to bond the pads of the connection circuit board with the pads of the display panel, particularly due to the increasing resolution of display devices, which necessitates more precise alignment. This issue arises as the size of the pads on these boards is reduced and the pitch decreases. Accordingly, it can be difficult to precisely align the connection circuit board with the display panel. A misalignment can lead to ineffectual or faulty electrical connections between these components.

### SUMMARY

Embodiments of the present disclosure may provide a display device in which pads provided in a connection circuit board and pads provided in a display panel are precisely bonded to each other to enable implementation of a high-resolution image, with increased reliability of electrical connection, an electronic device including the display device, and a method of manufacturing the display device.

According to an aspect of an embodiment, a display device includes a display panel. The display panel includes a display area having pixels and a non-display area including a panel pad group. The panel pad group includes a plurality of panel pads arranged in a first direction and connected one of the pixels to receive one or more signals. The panel pad group further includes an additional pad portion arranged in a lengthwise direction of each of the plurality of panel pads and spaced apart from the panel pads, and the additional pad portion includes a first additional pad and a second additional pad that are sequentially spaced apart from one another in the lengthwise direction of the panel pads.

In the present embodiment, the first additional pad and the second additional pad may overlap with an extension line that passes through centers of the panel pads in a widthwise direction of the panel pads, and extends in the lengthwise direction of the panel pads.

In the present embodiment, the first additional pad and the second additional pad may be arranged parallel to each other.

In the present embodiment, the panel pads and the additional pad portion may be arranged parallel to each other.

In the present embodiment, the second additional pad may be arranged to closer to the display area in the lengthwise direction of the panel pads than the first additional pad.

In the present embodiment, at least two of the plurality of panel pads may be inclined and are not parallel to each other.

In the present embodiment, a width of one end of the panel pad group that is closest to the display area may be greater than a width of another end of the panel pad group that is close to an edge of the display panel.

In the present embodiment, a width of the panel pad group in the first direction may gradually decrease away from the display area.

In the present embodiment, centers of the panel pads, the first additional pad, and the second additional pad may be all positioned on a straight line.

In the present embodiment, the display device may further include a connection circuit board including a connection pad group including a plurality of connection pads that are arranged in the first direction on the connection circuit board, and the connection circuit board may deliver the signals to the panel pad group.

In the present embodiment, each of the plurality of connection pads may be arranged to overlap with at least one area of each of the panel pad, the first additional pad, and the second additional pad.

In the present embodiment, the plurality of connection pads of the connection pad group may correspond to and electrically connect to the plurality of panel pads of the panel pad group, respectively.

In the present embodiment, the connection circuit board may include a plurality of connection circuit boards that are arranged in the first direction.

In the present embodiment, the panel pad group may include a plurality of panel pad groups that are arranged to correspond to the plurality of connection circuit boards, and the plurality of panel pad groups may correspond to and electrically connect to the plurality of connection circuit boards, respectively.

In the present embodiment, the display device may further include a third additional pad arranged between the first additional pad and the second additional pad.

According to an aspect of another embodiment, a method of manufacturing a display device includes forming a display panel including a display area with pixels and a non-display area including a panel pad group, the panel pad group including a plurality of panel pads aligned in a first direction, and an additional pad portion positioned spaced apart from the panel pads on a straight line extending in a lengthwise direction of each of the plurality of panel pads, forming a connection circuit board including a connection pad group including a plurality of connection pads aligned in the first direction, and connecting the display panel to the connection circuit board such that one of the connection pads overlaps with one of the panel pads and the additional pad portion.

In the present embodiment, the additional pad portion may include a first additional pad and a second additional pad that are sequentially spaced in a straight line extending in the lengthwise direction of the panel pads, and the connecting of the display panel to the connection circuit board may include causing each of the plurality of connection pads to overlap with and connect to at least one of the panel pads, the first additional pad, and the second additional pad.

In the present embodiment, the method may further include, before the connecting of the display panel to the connection circuit board, inspecting alignment of the panel pad group and the connection pad group.

In the present embodiment, the inspecting of the alignment of the panel pad group and the connection pad group may include generating a first virtual line connecting centers of the first additional pad and the second additional pad, and then measuring a difference between the first virtual line and a second virtual line connecting centers of the connection pads.

According to an aspect of another embodiment, an electronic device includes a controller, a power module, a display panel and a scan driver. The controller is configured to generate a scan input signal. The power module is configured to generate a scan input voltage. The display panel includes a display area having pixel circuits, and a non-display area surrounding the display area. The scan driver is arranged in the non-display area and is configured to receive the scan input signal and the scan input voltage and output a scan signal to the pixel circuits. The non-display area includes a panel pad group. The panel pad group includes a plurality of panel pads arranged in a first direction and connected to one of the pixel circuits. The panel pad group further includes an additional pad portion arranged in a lengthwise direction of each of the plurality of panel pads and spaced apart from the panel pads. The additional pad portion includes a first additional pad and a second additional pad that are sequentially spaced in the lengthwise direction of the panel pads.

### BRIEF DESCRIPTION OF THE DRAWINGS

The above and other aspects and features of certain embodiments of the disclosure will be more apparent from the following description taken in conjunction with the accompanying drawings, in which:

FIG. 1 is a plan view schematically illustrating a display device according to an embodiment of the present disclosure;

FIG. 2 is a cross-sectional view schematically illustrating an example of a cross-section taken along line I-I′ of FIG. 1;

FIG. 3 is a cross-sectional view schematically illustrating another example of a cross-section taken along line I-I′ of FIG. 1;

FIG. 4 is a plan view schematically illustrating a portion of the display device separated from portion A of FIG. 1;

FIG. 5 is a plan view schematically illustrating the display device in portion A of FIG. 1;

FIG. 6 is a cross-sectional view schematically illustrating a cross-section taken along line II-II′ of FIG. 1;

FIG. 7 is a cross-sectional view schematically illustrating a cross-section taken along line III-III′ of FIG. 1;

FIG. 8 is a plan view schematically illustrating a portion of a display device according to an embodiment of the present disclosure;

FIG. 9 is a plan view schematically illustrating a portion of a display device according to an embodiment of the present disclosure;

FIG. 10 is a plan view schematically illustrating a portion of a display device according to an embodiment of the present disclosure;

FIGS. 11 to 14 are plan views illustrating some operations of a method of manufacturing a display device, according to an embodiment of the present disclosure; and

FIG. 15 is a block diagram of an electronic device according to embodiments of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

As the present disclosure allows for various changes and numerous embodiments, particular embodiments will be illustrated in the drawings and described in detail. Features of the present disclosure and a method of achieving the same should become clear with embodiments described below in detail with reference to the drawings. However, the present disclosure is not limited to the embodiments disclosed below, but may be implemented in various forms.

In the following embodiments, terms such as “first,” “second,” etc., are used only to distinguish one component from another, and such components must not be limited by these terms.

In the following embodiments, the singular expression also includes the plural meaning as long as it is not inconsistent with the context.

In the following embodiments, the terms “comprise”, “include”, “have”, and the like used herein specify the presence of stated features or components, but do not preclude the presence or addition of one or more other features or components.

In the following embodiments, when a unit, area, or component is referred to as being “on” another unit, area, or component, it may be directly or indirectly on the other unit, area, or component, that is, one or more intervening units, areas, or components may be present therebetween.

In the following embodiments, when a component is referred to as being “connected to” or “coupled to” another component, the component may be directly connected to or in direct contact with the other component or intervening components may be present therebetween, unless clearly defined otherwise in the context.

For convenience of description, the magnitude of components in the drawings may be exaggerated or reduced. For example, because the size and/or thickness of each component illustrated in the drawing may be shown for convenience of description, the present disclosure is not necessarily limited to those illustrated in the drawing.

Hereinafter, embodiments of the present disclosure will be described below in detail with reference to the accompanying drawings, and when the embodiments of the present disclosure are described with reference to the drawings, the same or corresponding components are given the same reference numerals, and repetitive descriptions thereof will be omitted.

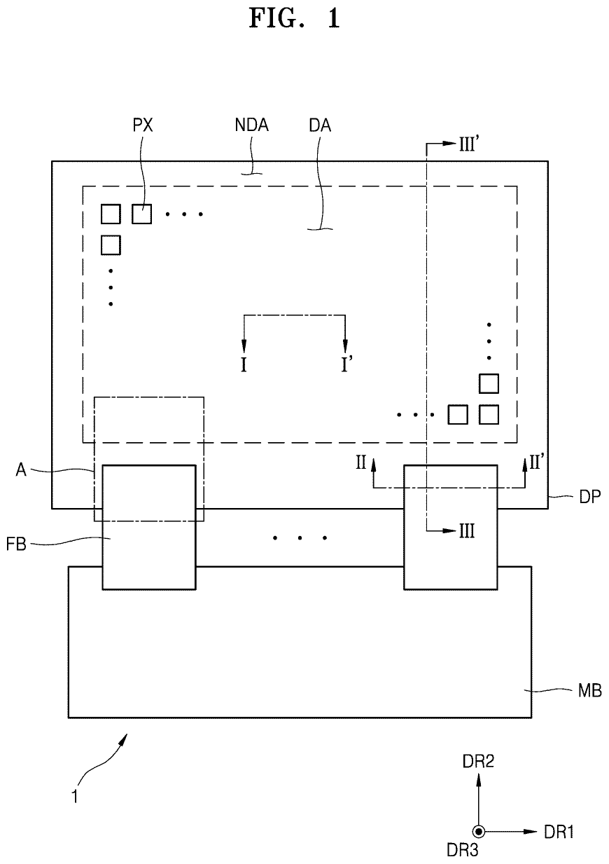

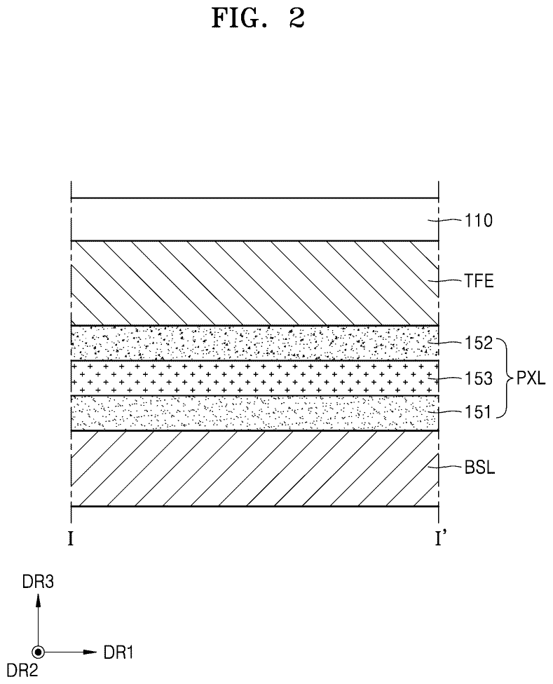

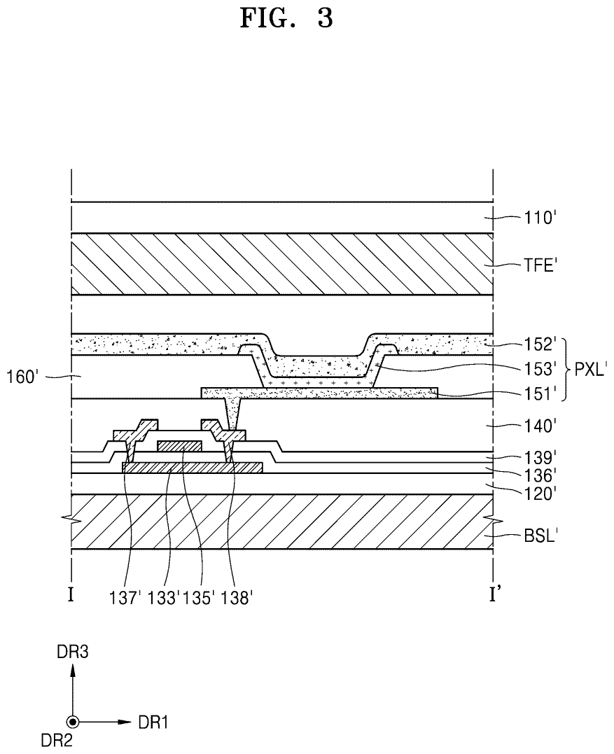

FIG. 1 is a plan view schematically illustrating a display device according to an embodiment of the present disclosure, FIG. 2 is a cross-sectional view schematically illustrating an example of a cross-section taken along line I-I′ of FIG. 1, and FIG. 3 is a cross-sectional view schematically illustrating another example of a cross-section taken along line I-I′ of FIG. 1.

Referring to FIG. 1, a display device 1 may include a display panel DP. In addition, in an alternative embodiment, the display device 1 may additionally include a connection circuit board FB or the connection circuit board FB and the main circuit board MB. The display panel DP, the connection circuit board FB and the main circuit board MB may be electrically connected to each other.

The display panel DP may include a display area DA and a non-display area NDA. The display area DA is a portion where an image is displayed, and the non-display area NDA surrounding the display area DA may be a portion where circuits and/or signal lines for generating and/or delivering various signals to be applied to the display area DA are arranged.

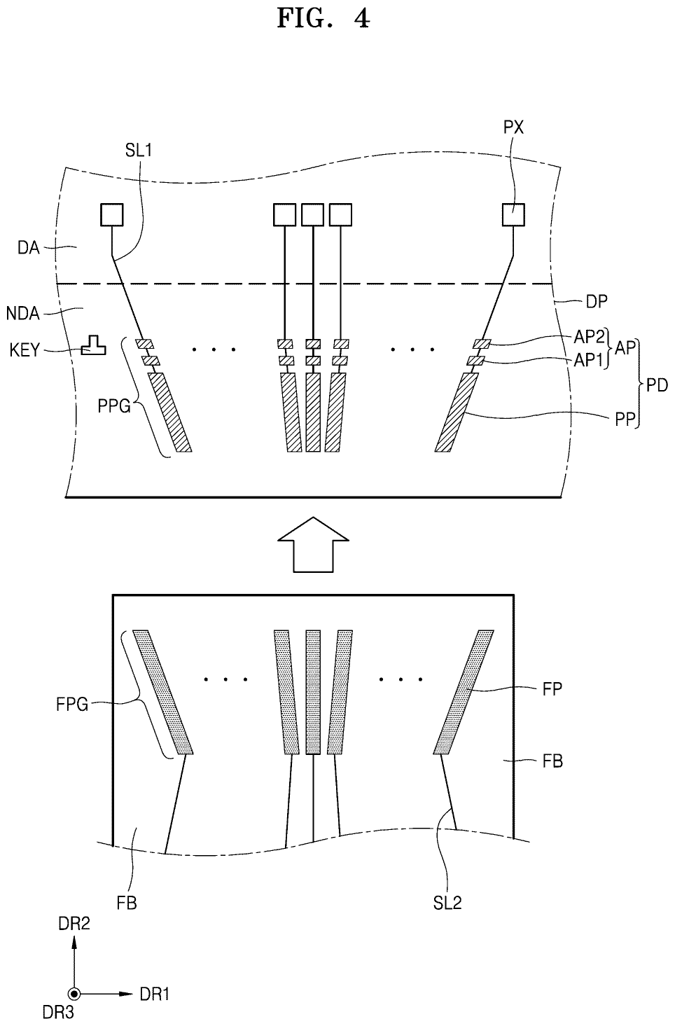

A plurality of pixels PX configured to receive signals from first signal wires SL1 (see FIG. 4) may be arranged in the display area DA of the display panel DP. In the present embodiment, each of the pixels PX may receive an electrical signal to display light to form an image. The pixels PX may be arranged in a matrix form to be spaced apart from each other in a first direction DR1 and a second direction DR2. The second direction DR2 may be perpendicular to the first direction DR1. The display panel DP may display various images by controlling the pixels PX. However, FIG. 1 illustrates merely an example, and some components of the pixels PX may be arranged to overlap with each other on a plane, and are not limited to any one embodiment.

Each of the pixels PX may include a display element and a driving element. The display element may include various embodiments. For example, the display element may include at least one of a liquid crystal capacitor, an organic light-emitting element, an electrophoretic element, and an electrowetting element. However, this is merely an example, and the display element may include various embodiments as long as it may implement an image according to an electrical signal, and is not limited to any one embodiment.

The driving elements control driving of the display elements of each pixel PX, respectively. The driving element may include a thin-film transistor. According to an embodiment of the present disclosure, the display panel DP may be driven by an active method in which each pixel PX may be independently controlled.

Signal lines such as scan lines, data lines, driving voltage lines, common voltage lines, and/or initialization voltage lines may be arranged in the display area DA. Each pixel PX may be connected to a scan line, a data line, a driving voltage line, a common voltage line, and/or an initialization voltage line, to receive a scan signal, a data voltage, a driving voltage, a common voltage, and/or a driving voltage from these signal lines. The pixel PX may include a light-emitting element such as a light-emitting diode. In addition, touch electrodes may be arranged in the display area DA of the display panel DP to detect a touch from a user's finger, etc.

Referring to FIG. 2, which schematically illustrates a cross-section of a portion of the display area DA of the display panel DP according to an example, the display panel DP may include a pixel layer PXL capable of providing visible light to the user. The types of pixels PX included in the pixel layer PXL may vary, and in the present embodiment, an example will be described in which the pixels PX are organic light-emitting elements.

Hereinafter, the display panel DP will be described in detail. The display panel DP may include the pixel layer PXL disposed on a substrate BSL. In an alternative embodiment, the display panel DP may further include an encapsulation layer TFE and an optical functional layer 110.

The substrate BSL may be formed by using various materials. As a specific example, the substrate BSL may be formed of glass, metal, or other organic materials.

In an alternative embodiment, the substrate BSL may be formed of a flexible material. For example, the substrate BSL may be formed to be easily bendable, foldable, or rollable.

In addition, for example, the substrate BSL may contain an ultra-thin glass, or a metal or plastic material, and for example, when using a plastic material, may contain polyimide (PI). As another specific example, the substrate BSL may contain at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polycarbonate, triacetate cellulose, and cellulose acetate propionate.

The pixel layer PXL may be formed on the substrate BSL and may include a first electrode 151, a second electrode 152, and an intermediate layer 153. In detail, the first electrode 151 may be formed on the substrate BSL, the second electrode 152 may be formed above the first electrode 151, and the intermediate layer 153 may be formed between the first electrode 151 and the second electrode 152.

A buffer layer may be further formed above the first electrode 151 and the substrate BSL. The buffer layer may provide a flat surface on the substrate BSL and may block moisture or gas infiltrating through the substrate BSL. For example, the buffer layer may be disposed between the first electrode 151 and the substrate BSL to prevent moisture or gas from infiltrating through the substrate BS into the first electrode 151.

The first electrode 151 may function as an anode, and the second electrode 152 may function as a cathode, or vice versa. In a case in which the first electrode 151 functions as an anode, the first electrode 151 may be provided to include ITO, IZO, ZnO, In₂O₃, etc. having a high work function. In addition, depending on the purpose and design conditions, the first electrode 151 may further include a reflective film formed of Ag, Mg, Al, Pt, Pd, Au, Ni, Nd, Ir, Cr, Li, Yb, Ca, etc.

In a case in which the second electrode 152 functions as a cathode, the second electrode 152 may be formed of a metal such as Ag, Mg, Al, Pt, Pd, Au, Ni, Nd, Ir, Cr, Li, Ca, etc. In addition, the second electrode 152 may include ITO, IZO, ZnO, In₂O₃, etc. to enable light transmission.

The intermediate layer 153 includes at least an organic light-emitting layer. In addition, the intermediate layer 153 may optionally include at least one of a hole injection layer, a hole transport layer, an electron transport layer, and an electron injection layer, in addition to the organic light-emitting layer. When a voltage is applied to the first electrode 151 and the second electrode 152, visible light is generated in the intermediate layer 153, particularly in the organic light-emitting layer of the intermediate layer 153.

The encapsulation layer TFE may be arranged on the pixel layer PXL to protect the pixels PX. The encapsulation layer TFE may protect the pixel layer PXL from external impact, and may reduce or prevent infiltration of external foreign substances, moisture, etc.

The encapsulation layer TFE may be formed as one of various types. In an alternative embodiment, the encapsulation layer TFE may be made of a transparent glass material containing SiO₂ as a main component. In another alternative embodiment, the encapsulation layer TFE may be formed of a light-transmissible plastic material. In another alternative embodiment, the encapsulation layer TFE may be formed by using an inorganic film or an organic film. In addition, as another alternative embodiment, the encapsulation layer TFE may be formed by stacking one or more organic films and one or more inorganic films, and optionally, the organic films and the inorganic films may be alternately stacked.

The display panel DP may provide an image in an upward direction, that is, toward the top in a third direction DR3, that is, toward the optical functional layer 110. The optical functional layer 110 may include a base material and optical functional particles.

The display panel DP may include a thin-film transistor configured to deliver, to the pixels PX, signals used to drive the pixels PX. This will be described in detail with reference to FIG. 3.

FIG. 3 is a diagram illustrating a modified example of FIG. 2. Referring to FIG. 3, the display panel DP may include a substrate BSL′, a pixel layer PXL′, a thin-film transistor, and an encapsulation layer TFE′.

The thin-film transistor may include an active layer 133′, a gate electrode 135′, a source electrode 137′, and a drain electrode 138′. This will be described in detail. A buffer layer 120′ may be formed on the substrate BSL′. The buffer layer 120′ prevents infiltration of impure elements through the substrate BSL and provides a flat surface on the substrate BSL′, and may be formed of various materials capable of performing these functions. The buffer layer 120′ is an optional component and thus may be omitted.

The active layer 133′ may be arranged in a certain pattern on the buffer layer 120′. The active layer 133′ may be formed of an inorganic semiconductor material such as silicon, may be formed of an organic semiconductor material in an alternative embodiment, and may contain an oxide semiconductor material in another alternative embodiment.

A gate insulating film 136′ may be formed on the active layer 133′. The gate insulating film 136′ may be formed of various insulating materials, and may be formed by using, for example, an oxide or a nitride.

The gate electrode 135′ may be formed on the gate insulating film 136′ to correspond to a certain area of the active layer 133′. The gate electrode 135′ may be formed of a material with high conductivity. For example, the gate electrode 135′ may contain Au, Ag, Cu, Ni, Pt, Pd, Al, or Mo, and may include an alloy such as an Al: Nd or Mo: W. However, this is merely an example and the present embodiment is not limited thereto, and the gate electrode 135′ may be formed of various other materials.

An interlayer insulating film 139′ may be formed to cover the gate electrode 135′. The source electrode 137′ and the drain electrode 138′ may be formed on the interlayer insulating film 139′. The source electrode 137′ and the drain electrode 138′ may be formed to be in contact with a certain area of the active layer 133′.

A passivation layer 140′ may be formed to cover the source electrode 137′ and the drain electrode 138′. A separate insulating film may be formed on the passivation layer 140′ to planarize the thin-film transistor.

Although not illustrated in FIG. 3, the pixel layer PXL′ may further include one or more thin-film transistors that may be electrically connected to the pixel layer PXL′, and may further include one or more capacitors that may be electrically connected to the pixel layer PXL′ or the one or more thin-film transistors.

A first electrode 151′ may be formed on the passivation layer 140′. The first electrode 151′ may be electrically connected to one of the source electrode 137′ and the drain electrode 138′. For example, the first electrode 151′ may be connected to the drain electrode 138′.

A pixel-defining film 160′ may be formed on the first electrode 151′ to expose a certain area of the first electrode 151′.

An intermediate layer 153′ may be formed on the first electrode 151′. The intermediate layer 153′ may include an organic light-emitting layer. In an alternative embodiment, the intermediate layer 153′ may further include at least one of a hole injection layer, a hole transport layer, an electron transport layer, and an electron injection layer, in addition to the organic light-emitting layer.

A second electrode 152′ may be formed on the intermediate layer 153′.

The encapsulation layer TFE′ may be arranged on the pixel layer PXL′ to protect the pixels PX.

In an alternative embodiment, the display panel DP may further include an optical functional layer 110′. The optical functional layer 110′ may include layers for light filtering, light polarization, light enhancement, or reducing glare.

The non-display area NDA may be adjacent to the display area DA. The non-display area NDA may be arranged on at least one side of the display area DA on the display panel DP. For example, the non-display area NDA may surround the display area DA. In FIG. 1, a boundary between the display area DA and the non-display area NDA is indicated by a dotted line. However, this is merely an example, and the non-display area NDA may have various shapes as long as it is adjacent to the display area DA, and is not limited to any one embodiment.

In addition, the non-display area NDA may be an area to which one end of the connection circuit board FB is coupled. As shown in FIG. 4, a plurality of panel pads PP for electrically connecting to the connection circuit board FB may be arranged in the non-display area NDA. The display panel DP may be electrically coupled to external components such as the connection circuit board FB and the main circuit board MB, via the non-display area NDA.

A driving unit (e.g., driving circuit) configured to generate and/or process various signals for driving the display panel DP may be located in the non-display area NDA. The driving unit may include a data driving unit (e.g., a data driver) configured to apply a data signal to a data line, a gate driving unit (e.g., a gate or scan driver) configured to apply a gate signal to a scan line, and a signal control unit (e.g., a timing controller) configured to control the data driving unit and the gate driving unit. Data signals, etc. may be applied to the pixels PX at a certain timing according to a scan signal generated by the gate driving unit.

The connection circuit board FB may be arranged in the non-display area NDA of the display panel DP to connect the main circuit board MB to the display panel DP. The connection circuit board FB may be arranged on one side of the display panel DP extending in the second direction DR2.

A plurality of connection circuit boards FB may be provided and arranged spaced apart from each other in the first direction DR1 in the non-display area NDA. However, this is an example and the connection circuit board FB may be provided as a single component and is not limited to any one embodiment.

The connection circuit board FB may be flexible. Accordingly, the connection circuit board FB connected to the display panel DP may bend such that other components connected to the connection circuit board FB, such as the main circuit board MB, are arranged on the rear surface of the display panel DP.

A plurality of connection pads FP may be arranged on the connection circuit board FB to be electrically connected to the display panel DP. The connection circuit boards FB may be connected to the panel pads PP located in the non-display area NDA of the display panel DP to overlap with the panel pads PP, and thus electrically connected to the display panel DP via the panel pads PP. The connection circuit board FB may be arranged to correspond to the non-display area NDA to deliver various electrical signals to the display area DA via the panel pads.

The main circuit board MB may be connected to the connection circuit boards FB, and may be connected to one end of the connection circuit board FB that is connected to the display panel DP, and to the other end of the connection circuit board FB on the opposite side, among the connection circuit boards FB.

The main circuit board MB may provide the display panel DP with image data, a control signal, a power voltage, etc. The main circuit board MB is a wiring board distinct from the connection circuit board FB, and may include active elements and passive elements. The main circuit board MB may be flexible or rigid and is not limited to any one embodiment.

A processor and/or a memory may be arranged in the main circuit board MB. For example, in a case in which the display device 1 is applied to a mobile communication terminal, the processor may include a central processing unit, a graphics processing unit, and/or an application processor including a modem, etc. The connection circuit board FB may be bent such that the main circuit board MB may be positioned on the rear surface of the display panel DP in a third direction DR3.

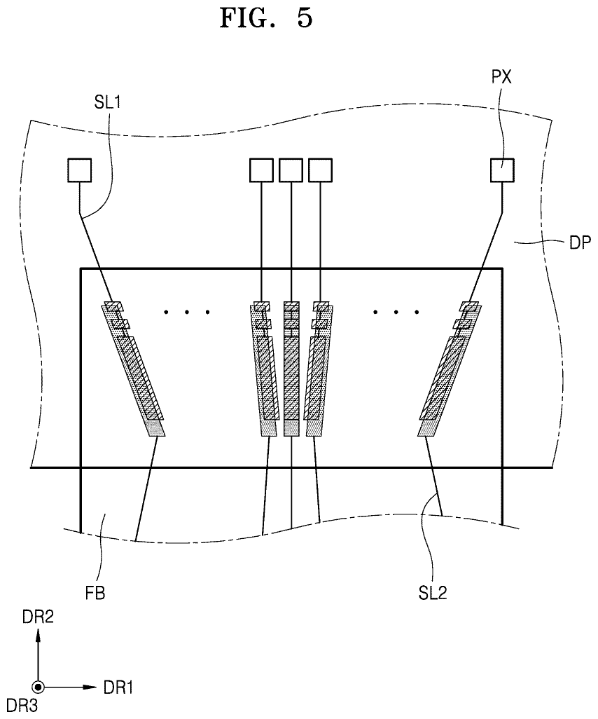

FIG. 4 is a plan view schematically illustrating a portion of the display device separated from portion A of FIG. 1, and FIG. 5 is a plan view schematically illustrating the display device in portion A of FIG. 1.

A panel pad group PPG may be arranged in the non-display area NDA of the display panel DP. FIG. 4 illustrates one panel pad group PPG, but a plurality of panel pad groups PPG may be arranged in the non-display area NDA. Each of the plurality of panel pad groups PPG may correspond to one connection pad group FPG. A plurality of panel pad groups PPG may be arranged to correspond to a plurality of connection circuit boards FB, and the plurality of panel pad groups PPG may correspond to and electrically connect to the plurality of connection circuit boards FB, respectively.

The panel pad group PPG may include a plurality of panel pads PP, a plurality of first additional pads AP1, and a plurality of second additional pads AP2, which are arranged in the first direction DR1.

The panel pad group PPG has a width in the first direction DR1, and the width of the panel pad group PPG may vary by area. In an embodiment, one end of the panel pad group PPG that is closer to the display area DA has a width greater than that of the other end of the panel pad group PPG that is closer to an edge of the display panel DP. In addition, for example, the width of the panel pad group PPG may gradually decrease away from the display area DA.

The panel pad group PPG may include a plurality of panel pads PP arranged to receive one or more signals to be delivered to the display area DA. The panel pads PP may be arranged in the non-display area NDA in the first direction, and may be spaced apart from each other.

The panel pad PP may extend between an edge of the display panel DP and the display area DA. In an embodiment, at least two of the plurality of panel pads PP are not arranged in parallel to each other but are inclined. For example, some of the panel pads PP may have different inclinations with respect to the second direction DR2.

Regarding a spacing between one panel pad PP and another panel pad PP that is closest thereto, the spacing on the side of an edge of the display panel DP may be wider that on the side of the display area DA. That is, the spacing may gradually decrease away from the display area DA. In addition, a spacing between one panel pad PP and another panel pad PP closest thereto may be at least a distance at which no short circuit occurs between the adjacent panel pads PP. For example, the panel pads PP may be positioned spaced part from one another and as close as possible to one another such that the chances of a short circuit is minimized.

The panel pad PP may have various shapes. The panel pad PP may have, for example, the shape of a quadrangle, specifically, a rectangle, a trapezoid, a parallelogram, or the like.

For example, the panel pads PP may have the same shape. As another example, the panel pads PP may have the same length but different inclinations. As another example, the panel pads PP may have the same length but different widths.

The panel pad PP may be electrically connected to the connection pad FP of the connection circuit board FB to receive a signal. The panel pad PP may deliver a signal received from the connection circuit board FB, to the pixel PX through the first signal wire SL1. That is, the plurality of first signal wires SL1 may extend from the display area DA to be connected to the plurality of panel pads, respectively. The panel pads PP may electrically connect the connection circuit board FB to the display panel DP.

When the display device 1 has a high resolution, the sizes of the panel pads PP and the connection pads FP decrease and the pitch decreases, making it difficult to precisely adjust the panel pads PP and the connection pads FP and bond them. This issue may be resolved by arranging additional pad portions AP along an extension line of the length of the panel pads PP.

The additional pad portions AP may be arranged in a portion of the non-display area NDA between the panel pads PP and the display area DA. The additional pad portions AP may be arranged in the first direction in which the panel pads PP are arranged.

The additional pad portions AP may be arranged along the lengthwise direction of the panel pads PP, and may be spaced apart from the panel pads PP. For example, an additional pad portion AP may extend in a same direction in which a corresponding panel pad PD extends. The panel pads PP and the additional pad portions AP may be formed parallel to each other.

Some of the panel pads PP have different inclinations, and thus, it may not be easy to accurately bond the panel pads PP to the connection pads FP. Rather than simply aligning and then connecting the panel pad PP to the connection pads FP, it may be easier to determine the alignment of the panel pads PP and the connection pads FP by measuring a difference ΔD between a first virtual line VL1, which connects the centers of the additional pad portions AP, and a second virtual line VL2, which connects the centers of the connection pads FP.

In addition, it is possible to drive a system configured to automatically control the alignment of the panel pads PP and the connection pads FP by feeding back measurements regarding the alignment. For example, the system may include a camera to capture images of the panel pads PP and the connection pads FP, a processor to process the captured images to determine the virtual lines VL1 and VL2, measure the difference ΔD from the virtual lines VL1 and VL2, and an actuator to move the display area panel DP and/or the connection circuit board FB based on the measured difference ΔD such that the panel pads PP and the connection pads FP better align to create a more secure connection. As a result, the reliability of the display device 1 may be increased by more precisely adjusting the positions of the display panel DP and the connection circuit board FB, and a high-resolution display device 1 may be produced.

The additional pad portion AP may include a first additional pad AP1 and a second additional pad AP2 that are sequentially arranged spaced apart from each other in the lengthwise direction of the panel pads PP. The second additional pad AP2 may be arranged closer to the display area DA in the lengthwise direction of the panel pads PP than the first additional pad AP1.

Because a plurality of panel pads PP are arranged, a plurality of first additional pads AP1 and a plurality of second additional pads AP2 may arranged along the extension lines of the respective panel pads PP. That is, like the panel pads PP, the first additional pads AP1 and the second additional pads AP2 may be arranged in the first direction in the non-display area NDA.

The plurality of first additional pads AP1 and the plurality of second additional pads AP2 may have inclinations corresponding to the extents to which the respective panel pads PP are inclined with respect to the second direction DR2.

The first additional pads AP1 and the second additional pads AP2 may be formed parallel to each other. When an extension line is defined as passing through the centers of the panel pads PP in the widthwise direction of the panel pads PP with respect to the first direction and extending in the lengthwise direction of the panel pads PP, the first additional pads AP1 and the second additional pads AP2 may overlap with the extension line. The centers of the panel pads PP, the centers of the first additional pads AP1, and the centers of the second additional pads AP2 may all be positioned on a straight line. For example, a panel pad PP, a first additional pad AP1 and a second additional pads AP2 may be arranged along a same direction such that they are in alignment with one another.

The first additional pads AP1 and the second additional pads AP2 may have various shapes, for example, the shape of a quadrangle, a diamond, a triangle, or the like. The first additional pads AP1 and the second additional pads AP2 may have the same shape.

For example, the first additional pads AP1 may have the same shape as each other. As another example, the first additional pads AP1 may have the same length but different inclinations. As another example, the first additional pads AP1 may have the same length but different widths.

For example, the second additional pads AP2 may have the same shape as each other. As another example, the second additional pads AP2 may have the same length but different slopes. As another example, the second additional pads AP2 may have the same length but different widths.

The first additional pads AP1 and the second additional pads AP2 may overlap with and connect to the connection pads FP of the connection circuit board FB. By measuring the distance difference ΔD in the first direction DR1 between the first virtual line VL1, which connects the centers of the first additional pads AP1 and the second additional pads AP2, and the second virtual line VL2, which passes through the centers of the widths of the connection pads FP in the lengthwise direction of the connection pads FP, it is possible to determine whether the panel pads PP and the connection pads FP are aligned or by how much they are misaligned.

In addition, it is possible to drive a system configured to automatically control the alignment of the panel pads PP and the connection pads FP by feeding back measurements regarding the alignment.

The first additional pads AP1 and the second additional pads AP2 are easily recognized as physical pads, and the reliability of alignment determination may be increased by using the first virtual line VL1 connecting the centers of the first additional pads AP1 and the second additional pads AP2. Accordingly, the defect rate of the display device 1 may be reduced, and a high-resolution display device 1 may be produced.

By connecting both the first additional pads AP1 and the second additional pads AP2 to the connection pads FP, a system is established that facilitates alignment. These additional pads AP1 and AP2 are spaced apart from the panel pads PP and from each other. This configuration enables construction of a system capable of facilitating the alignment of the panel pads PP and the connection pads FP, and measuring the alignment of the panel pads PP and the connection pads FP more precisely to automatically control the alignment.

By forming a plurality of additional pads rather than one additional pad, the reliability of the virtual line connecting the additional pads may be increased. Third additional pads may be additionally included between the panel pads PP and the display area DA in the lengthwise direction of the panel pads PP. For example, the third additional pads may be arranged between the first additional pads AP1 and the second additional pads AP2.

If third additional pads are included, alignment of the pads PP and FP may be achieved in two ways. One method measures a difference between the second virtual line VL2 and a virtual line that connects the centers of the first additional pad AP1, the second additional pad AP2, and the third additional pads. Alternatively, alignment can be determined by measuring the difference between the second virtual line VL2 and a virtual line that connects the centers of the first additional pads AP1, the second additional pads AP2, and the third additional pads, excluding any centers that significantly deviate or deviate by more than a threshold amount from the average.

The connection circuit board FB may include the connection pad group FPG on one surface of the connection circuit board FB. While FIG. 4 illustrates one connection pad group FPG is included in one connection circuit board FB, the present disclosure is not limited thereto. For example, a plurality of connection pad groups FPG may be arranged in one connection circuit board FB. That is, the connection circuit board FB may include at least one connection pad group FPG.

The shape of the connection pad group FPG may correspond to the shape of the panel pad group PPG. The connection pad group FPG may have a width in the first direction DR1, and the width of the connection pad group FPG may vary by area. For example, the width of the connection pad group FPG close to the display panel DP may be greater than the width of the connection pad group FPG close to the main circuit board MB, and specifically, the width of the connection pad group FPG may gradually increase toward an edge of the connection circuit board FB close to the display panel DP.

The connection pad group FPG may include a plurality of connection pads FP arranged in the first direction. The connection pad FP may serve as a passage for delivering a signal from the connection circuit board to the display panel DP.

The connection pad group FPG may correspond to the panel pad group PPG, and the connection pads FP may correspond to the panel pads PP, respectively. For example, one panel pad PP may be connected to one connection pad FP, and does not overlap with and connect to other panel pads PP.

Because the connection pads FP need to correspond to the respective panel pads PP as described above, the connection pads FP may be spaced apart from each other like the panel pads PP. The connection pad FP may extend in the second direction DR2. At least two of the plurality of connection pads FP may be arranged to be inclined without being arranged in parallel with some of the other connection pads FP. For example, the connection pads FP may have different inclinations with respect to the second direction DR2.

The connection pads FP may have various shapes. The connection pads FP may have, for example, the shape of a quadrangle, specifically, a rectangle, a trapezoid, a parallelogram, or the like.

For example, the connection pads FP may have the same shape. As another example, the connection pads FP may have the same length but different inclinations. As another example, the connection pads FP may have the same length but different widths.

The connection pads FP may deliver various signals generated by the display device 1, from the connection circuit board FB to the display panel DP through the panel pads PP. For example, a signal generated by the main circuit board MB may be delivered to the connection circuit board FB through second signal wires SL2, and then delivered to the display panel DP through the panel pads PP via the connection pads FP. The connection pads FP may electrically connect the connection circuit board FB to the panel pads PP.

The connection pads FP may also be connected to the additional pad portion AP. In detail, the connection pads FP may overlap with and connect to both the first additional pad AP1 and the second additional pad AP2. Each of the plurality of connection pads FP may be arranged to overlap with at least one area of each of the corresponding panel pad PP, the first additional pad AP1, and the second additional pad AP2. The plurality of connection pads FP of the connection pad group FPG may correspond to and electrically connect to the plurality of panel pads PP of the panel pad group PPG, respectively.

In an embodiment, the connection pad FP extends beyond the length of the panel pads PP to be connected to the first additional pad AP1 and the second additional pad AP2, to more accurately measure the difference ΔD between the first virtual line VL1, which connects the centers of the first additional pad AP1 and the second additional pad AP2, and the second virtual line VL2, which connects the centers of the connection pads FP. In an embodiment, a length of a connection pad FP is longer than a length of a corresponding panel PP so it may extend long enough to enable it to connect with one or more of the additional pads AP1 and/or AP2.

FIG. 5 illustrates that the width of the connection pad group FPG is slightly greater than the width of the panel pad group PPG, but the spacing between the plurality of connection pads FP belonging to the connection pad group FPG may be equal to the spacing between the panel pads PP belonging to the panel pad group PPG. Thus, the width of the connection pad group FPG may be equal to the width of the panel pad group PPG. In addition, the connection pad group FPG and the panel pad group PPG do not need to overlap with each other to coincide with each other precisely, and need only overlap with each other enough to ensure that the connection pads FP and the panel pads PP are connected to each other in a one-to-one correspondence. Thus, the connection pad group FPG may be slightly misaligned in the upward, downward, leftward, or rightward direction, from the position of the panel pad group PPG to the extent that no short circuits occur between the pads PP and FP corresponding to each other.

Referring to FIG. 5, as the panel pads PP of the display panel DP and the connection pads FP of the connection circuit board FB overlap with and come into contact with each other, the display panel DP and the connection circuit board FB may be electrically connected to each other. Here, a method of connecting the panel pads PP to the connection pads FP will be described in detail.

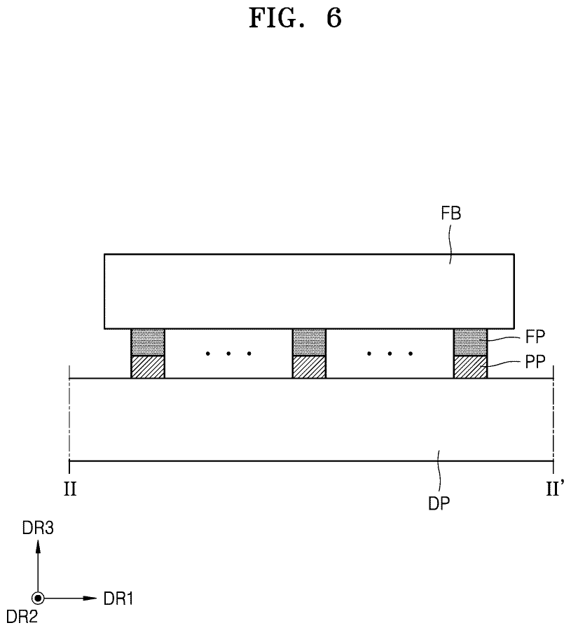

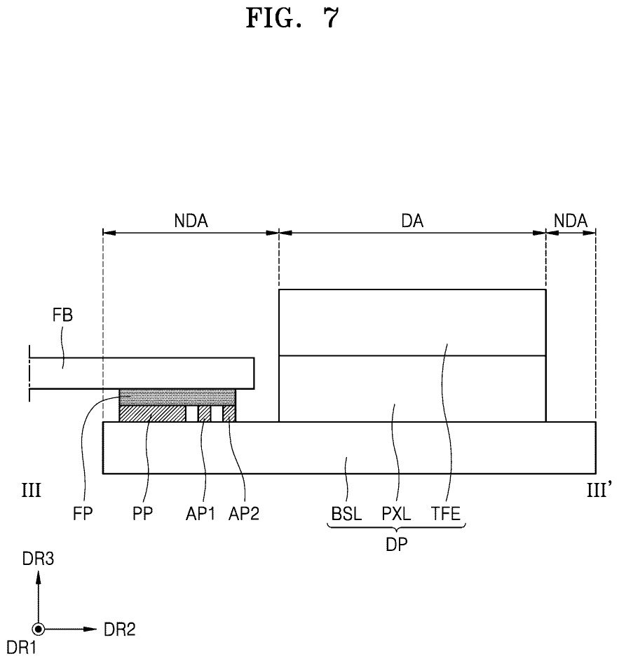

FIG. 6 is a cross-sectional view schematically illustrating a cross-section taken along line II-II′ of FIG. 1, and FIG. 7 is a cross-sectional view schematically illustrating a cross-section taken along line III-III′ of FIG. 1.

The plurality of panel pads PP arranged in the non-display area NDA of the display panel DP may overlap with the connection pads FP arranged on one surface of the connection circuit board FB, respectively, thereby electrically connecting the connection circuit board FB to the display panel DP.

For example, referring to FIG. 6, the width of the panel pads PP and the width of the connection pads FP are equal to each other, and the panel pads PP may be connected to the connection pads FP, respectively, as the width of the panel pads PP and the width of the connection pads FP correspond to each other. However, the width of the panel pads PP and the width of the connection pads FP may be different from each other in an alternate embodiment, and need not directly correspond to each other. Thus, the side surfaces of the panel pads PP and the connection pads FP may not exactly coincide with each other.

The panel pads PP and the connection pads FP may form appropriate widths to have structural stability to the extent that the panel pads PP and the connection pads FP overlap with and connect to each other, and to the extent that the panel pads PP and the connection pads FP connect to each other to sufficiently support the connection circuit board FB.

Referring to FIG. 7, the display panel DP may include the display area DA located in the middle of the display panel DP, and the non-display area NDA on both sides of the display area DA.

The non-display area NDA may be electrically connected to the connection circuit board FB in at least one area. In addition to the panel pads PP, the connection pads FP may overlap with and connect to the first additional pad AP1 and the second additional pad AP2, and the connection pads FP overlap with the first additional pad AP1 and the second additional pad AP2, facilitating determination of alignment of the panel pads PP and the connection pads FP. Accordingly, the reliability and electrical connection between the connection circuit board FB and the display panel DP may be increased. In an embodiment, a connection pad FP extends slightly beyond a corresponding second additional pad AP1 in the second direction DR2 in the non-display area NDA but does not extend into the display area DA.

The display panel DP may include the substrate BSL, the pixel layer PXL, and the encapsulation layer TFE, which are stacked in the third direction DR3 in a cross-sectional view.

The substrate BSL may be a base layer on which the pixel layer PXL is formed. The substrate BSL may be a single layer or may include a plurality of insulating layers. The substrate BSL may include at least one of a glass substrate, a plastic substrate, a film, and a stack including a plurality of organic films and/or a plurality of inorganic films, but is not limited to any one embodiment.

The substrate BSL may include driving elements and signal lines for the pixels PX as described above. Accordingly, the substrate BSL may have a stack structure of a plurality of conductive layers, a plurality of organic films, and/or a plurality of inorganic films.

The pixel layer PXL may be arranged on the substrate BSL. The pixel layer PXL may be electrically connected to driving elements and signal lines of the substrate BSL. The pixel layer PXL includes the display elements in the pixels PX as described above. For example, in a case in which the display panel DP is an organic light-emitting display panel, the pixel layer PXL may include an organic light-emitting layer. The display area DA may correspond to an area where the pixel layer PXL is arranged.

The encapsulation layer TFE may be arranged on the pixel layer PXL to cover the pixel layer PXL. The encapsulation layer TFE may protect the pixel layer PXL. The encapsulation layer TFE may also cover side surfaces of the pixel layer PXL. In addition, depending on the type of the display panel DP, the encapsulation layer TFE may be omitted or replaced with another display substrate.

The connection circuit board FB may be arranged in the non-display area NDA of the display panel DP to connect the main circuit board MB to the display panel DP. The connection circuit board FB may be arranged on one side of the display panel DP extending in the second direction DR2.

For example, a plurality of connection circuit boards FBs may be provided and arranged in the first direction DR1. As another example, the connection circuit board FB may be provided as a single component, and is not limited to any one embodiment.

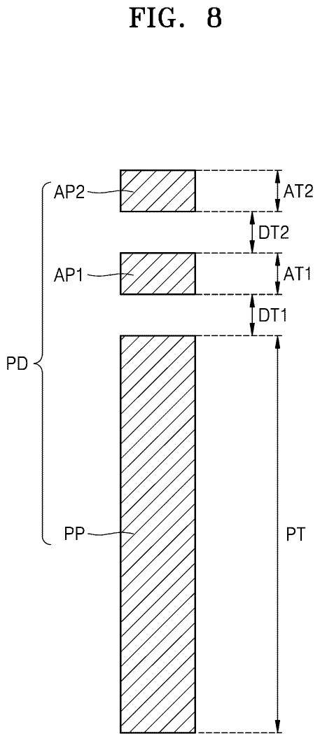

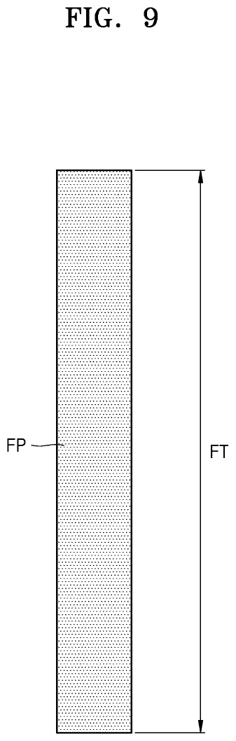

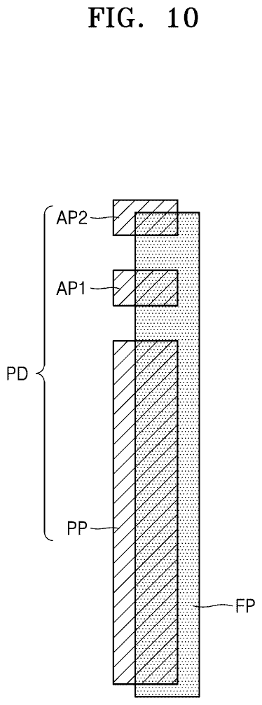

FIG. 8 is a plan view schematically illustrating a portion of a display device according to an embodiment of the present disclosure, FIG. 9 is a plan view schematically illustrating a portion of a display device according to an embodiment of the present disclosure, and FIG. 10 is a plan view schematically illustrating a portion of a display device according to an embodiment of the present disclosure.

A panel pad portion PD may include the panel pad PP, the first additional pad AP1, and the second additional pad AP2. The first additional pad AP1 and the second additional pad AP2 may be sequentially arranged to be spaced apart from each other on the extension line of the panel pad PP in the lengthwise direction. For example, the panel pad PP, the first additional pad AP1, and the second additional pad AP2 may be aligned along the extension line.

The panel pad PP and the first additional pad AP1 may have a first separation distance DT1 therebetween. For example, the first separation distance DT1 between the panel pad PP and the first additional pad AP1 may range from 5 micrometers (μm) to 20 μm. In a specific embodiment, the first separation distance DT1 is exactly or approximately 10 μm.

The first additional pad AP1 and the second additional pad AP2 may have a second separation distance DT2 therebetween. The second separation distance DT2 may need to have a sufficient value because the difference ΔD is determined between the first virtual line VL1, which connects the centers of the first additional pad AP1 and the second additional pad AP2, and the second virtual line VL2, which connects the centers of the connection pads FP. In an embodiment, the second separation distance DT2 is greater than the first separation distance DT1. For example, the second separation distance DT2 between the first additional pad AP1 and the second additional pad AP2 may range from 40 μm to 200 μm. In a specific embodiment, the second separation distance DT2 is exactly or approximately 100 μm.

A length AT1 of the first additional pad AP1 may be sufficiently long to allow a key KEY to recognize the presence of the first additional pad AP1. For example, the length AT1 of the first additional pad AP1 may range from 20 μm to 80 μm. As a specific embodiment, the length AT1 of the first additional pad AP1 may be exactly or approximately 50 μm.

Similar to the length AT1 of the first additional pad AP1, a length AT2 of the second additional pad AP2 may be sufficiently long to allow the key KEY to recognize the presence of the second additional pad AP2. For example, the length AT2 of the second additional pad AP2 may range from 20 μm to 80 μm. As a specific embodiment, the length AT2 of the second additional pad AP2 may be exactly or approximately 50 μm. In an alternative embodiment, the length AT2 of the second additional pad AP2 and the length AT1 of the first additional pad AP1 are equal to each other.

Because the connection pad FP needs to overlap with all of the panel pad PP, the first additional pad AP1 and the second additional pad AP2, a length FT of the connection pad FP may be at least greater than the length of the panel pad PP. In detail, the length FT of the connection pad FP may be greater than the sum of a length PT of the panel pad PP, the first separation distance DT1, the length AT1 of the first additional pad AP1, and the second separation distance DT2. For example, the length of the panel pad portion PD and the length FT of the connection pad FP may be equal to each other.

The width of the additional pad portion AP may have a sufficient value to enable the first virtual line VL1 connecting the centers of the additional pad portions AP to be determined as scanning progresses in the first direction DR1. For example, the width of the panel pad PP may be equal to the width of the additional pad portion AP.

The width of the connection pad FP may also have a sufficient value to enable the second virtual line VL2 connecting the centers of the connection pads FP to be determined as scanning progresses in the first direction DR1. For example, the width of the connection pad FP may be equal to the width of the additional pad portion AP. As another example, the width of the connection pad FP may be less than the width of the additional pad portion AP.

The connection pads FP, the additional pads AP1 and AP2, and the panel pads PP may be made of various materials. For example, the connection pad FP may be made of a material including nickel on a copper base, the panel pad PP may be made of a material including Ti on a copper base, and the additional pad may be made of a metal material having a high contrast for increasing the recognition rate.

The connection pad FP may overlap with and connect to, at least in part, the panel pad PP, the first additional pad AP1, and the second additional pad AP2. The connection pad FP only needs to come into contact with the panel pad PP, the first additional pad AP1 and, the second additional pad AP2, and significantly precise alignment may not be required.

That is, in FIG. 10, the panel pad portion PD and the connection pad FP slightly overlap to the right, maintaining a small separation distance. This arrangement ensures that the connection pad FP does not overlap with other panel pad portions PD, thereby avoiding short circuits by keeping a safe minimum distance. Moreover, the connection pad FP may be bonded to the panel pad portion PD even if is not perfectly aligned and is slightly offset in any direction, such as upward, downward, leftward, or rightward.

That is, one connection pad FP needs to be in contact with only one panel pad PP, one first additional pad AP1, and one second additional pad AP2, and may not be in contact with another panel pad PP, another first additional pad AP1 and another second additional pad AP2. Accordingly, the electrical reliability of the display device 1 may be increased, and short circuits may be prevented.

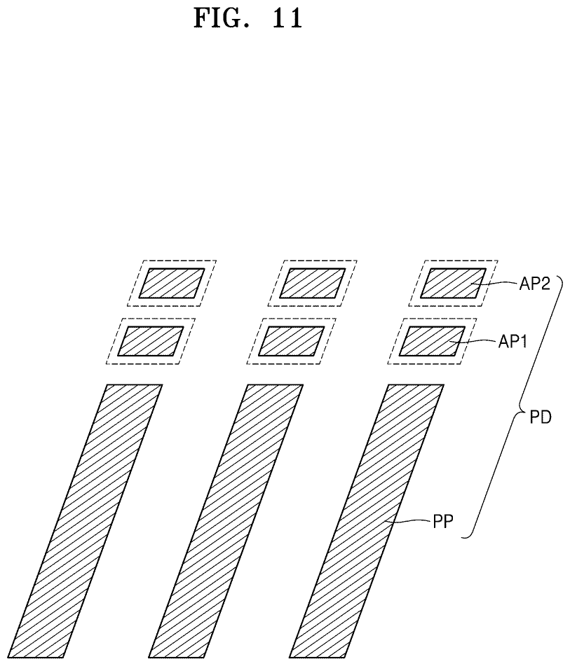

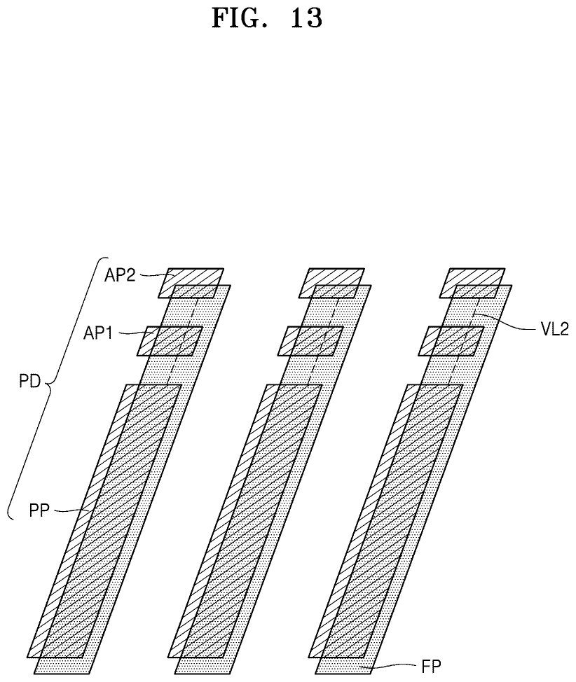

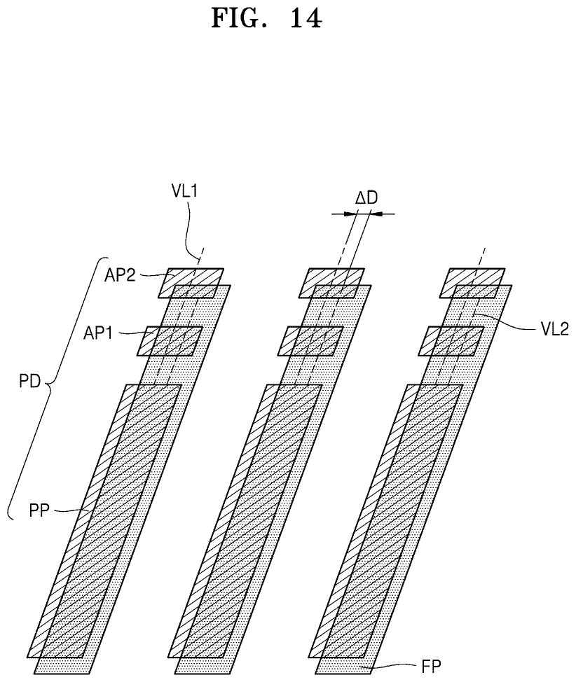

FIGS. 11 to 14 are plan views illustrating some operations of a method of manufacturing a display device, according to an embodiment of the present disclosure. Hereinafter, a method of manufacturing a display device and a method of aligning the panel pad portion PD and a connection pad FP, according to an embodiment of the present disclosure will be described.

The display device 1 may be manufactured by performing an operation of forming the display panel DP including the non-display area NDA in which the panel pad group PPG is arranged, wherein the panel pad group PPG includes a plurality of panel pads PP aligned in the first direction DR1, and the additional pad portion AP positioned to be spaced apart from the panel pads PP along a straight line extending in the lengthwise direction of each of the plurality of panel pads PP. The additional pad portion AP may include the first additional pad AP1 and the second additional pad AP2 that are sequentially arranged to be spaced apart from each other in the lengthwise direction of the panel pads PP, along a straight line extending in the lengthwise direction of the panel pads PP.

The display device 1 may be manufactured by further performing an operation of inspecting the alignment of the panel pad group PPG and the connection pad group FPG, after the operation of forming the display panel DP and an operation of forming the connection circuit board FB including the connection pad group FPG including a plurality of connection pads FP aligned in the first direction DR1.

In detail, because the panel pads PP have different inclinations, it is difficult to accurately align the panel pads PP and the connection pads FP by using an existing key KEY or mark when they are simultaneously shifted in the first direction DR1 and the second direction DR2, but this issue may be resolved by additionally arranging the additional pad portion AP.

The operation of inspecting the alignment of the panel pad group PPG and the connection pad group FPG may include an operation of generating the first virtual line VL1, which connects the centers of the first additional pad AP1 and the second additional pad AP2, and then measuring the difference ΔD between the first virtual line VL1 and the second virtual line VL2, which is the center line of the connection pads FP. In detail, the difference ΔD in the distance between the first virtual line VL1 and the second virtual line VL2 in the first direction may be measured.

In detail, first, the first additional pad AP1 and the second additional pad AP2 may be recognized as illustrated in FIG. 11. The key KEY may recognize the presence of the first additional pad AP1 and the second additional pad AP2 located in the non-display area NDA, and then, as scanning progresses, recognize the positions of the first additional pad AP1 and the second additional pad AP2.

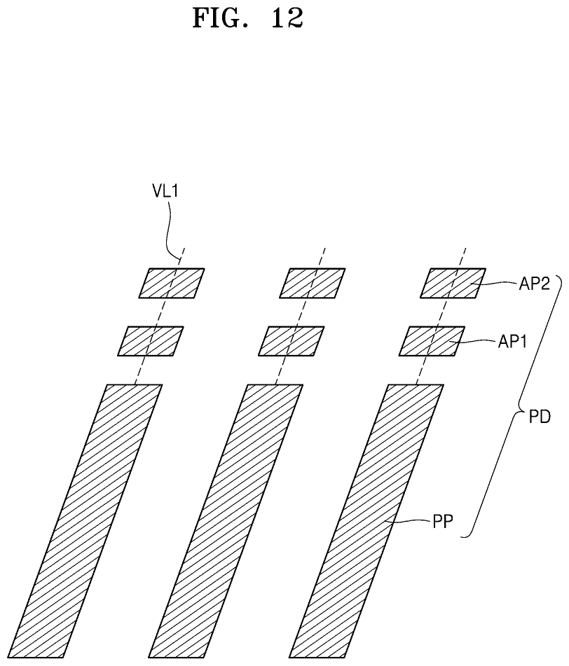

As scanning progresses, the centers of the first additional pad AP1 and the second additional pad AP2 may be measured as illustrated in FIG. 12, and the first virtual line VL1 connecting the centers of the first additional pad AP1 and the second additional pad AP2 may be generated. The scanning may be performed by the camera or the processor.

In addition, the second virtual line VL2 connecting the centers of the widths of the connection pads FP may be generated through scanning, and the difference ΔD between the first virtual line VL1 and the second virtual line VL2, specifically, the difference ΔD in the distance between the first virtual line VL1 and the second virtual line VL2 with respect to the first direction may be measured.

By measuring the difference ΔD in the distance between the first virtual line VL1 and the second virtual line VL2, it is possible to determine how well the additional pad portion AP and the connection pad FP are aligned. Because the additional pad portion AP is located on the extension line of the panel pads PP in the lengthwise direction, it is possible to determine how well the panel pad PP and the connection pad FP are aligned.

In addition, it is possible to drive a system configured to automatically adjust the alignment of the panel pads PP and the connection pads FP by feeding back measurements regarding the alignment. For example, the system may include actuators or robotics that physically adjust the position of the pads or the substrates on which they are mounted based on the measurements.

In the operation of inspecting the alignment of the panel pad group PPG and the connection pad group FPG, when the distance between the first virtual line VL1 and the second virtual line VL2 is greater than or equal to a preset distance, the alignment may be determined as being defective or misaligned. The preset distance may be at least a distance that may prevent short circuits between the panel pads PP that are closest to each other.

The display device 1 may be manufactured by further performing, after the operation of inspecting the alignment of the panel pad group PPG and the connection pad group FPG, an operation of connecting the display panel DP to the connection circuit board FB such that the connection pad FP overlaps with at least the panel pad PP and a portion of the additional pad portion AP.

The operation of connecting the display panel DP to the connection circuit board FB may include an operation of causing each of the plurality of connection pads FP to overlap with and connect to, at least in part, all of the panel pad PP, the first additional pad AP1 and the second additional pad AP2. For example, the process of attaching the display panel DP to the connection circuit board FB may involve ensuring that each of the multiple connection pads FP partially overlaps and connects with the panel pad PP, as well as with both the first additional pad AP1 and the second additional pad AP2.

In the display device 1 manufactured through the above-described operations, in a case in which the panel pads PP have different inclinations, even when the connection pad FP is connected slightly misaligned from the center of the panel pad PP in the first direction DR1 and the second direction DR2, the pads PP and FP may be aligned through the additional pad portion AP arranged along an extension line of the length of the panel pad PP, and then the connection circuit board FB and the display panel DP may be electrically connected to each other.

By finely tuning the positions of the connection circuit board FB and the display panel DP, particularly the alignment of the connection pads FP and the panel pads PP before bonding them, it is possible to manufacture a display device 1 with a small pitch capable that supports high resolution.

In addition, even with a small pitch, it is possible to generate a quality display device 1 in which the connection circuit board FB and the display panel DP are electrically connected to each other, which can help reduce the defect rate.

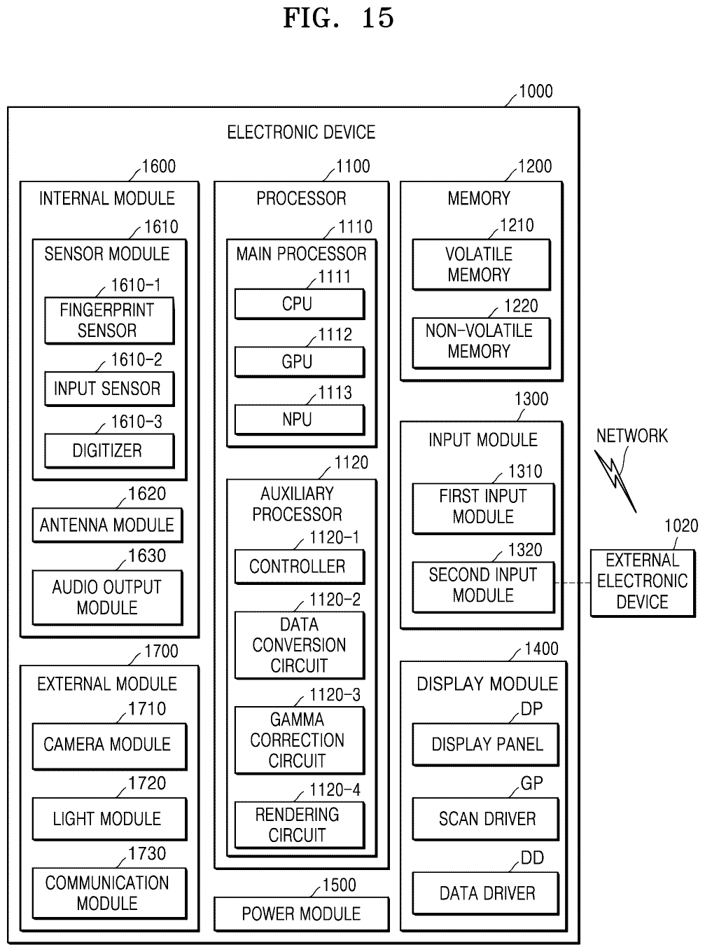

FIG. 15 is a block diagram of an electronic device according to embodiments of the present disclosure.

An electronic device 1000 outputs various pieces of information through a display module 1400 within an operating system. When a processor 1100 executes an application stored in a memory 1200, the display module 1400 provides application information to a user through the display panel DP.

The processor 1100 obtains an external input through an input module 1300 or a sensor module 1610, and executes an application corresponding to the external input. For example, when the user selects a camera icon displayed on the display panel DP, the processor 1100 obtains a user input through an input sensor 1610-2 and activates a camera module 1710. The processor 1100 delivers, to the display module 1400, image data corresponding to a captured image obtained through the camera module 1710. The display module 1400 may display an image corresponding to the captured image through the display panel DP.

As another example, when personal information authentication is performed in the display module 1400, a fingerprint sensor 1610-1 obtains input fingerprint information as input data. The processor 1100 compares the input data obtained through the fingerprint sensor 1610-1 with authentication data stored in the memory 1200, and executes an application according to a result of the comparison. The display module 1400 may display, through the display panel DP, information obtained through execution according to logic of the application.

As another example, when a music streaming icon displayed on the display module 1400 is selected, the processor 1100 obtains a user input through the input sensor 1610-2 and activates a music streaming application stored in the memory 1200. When a music execution command is input in the music streaming application, the processor 1100 activates an audio output module 1630 to provide the user with audio information corresponding to the music execution command.

The operation of the electronic device 1000 has been briefly described above. Hereinafter, a configuration of the electronic device 1000 will be described in detail. Some of the components of the electronic device 1000 to be described below may be integrated into one component and then provided, and one component of the electronic device 1000 may be separated into two or more components and then provided.

Referring to FIG. 15, the electronic device 1000 may communicate with an external electronic device 1020 via a network (e.g., a short-range wireless communication network or a long-range wireless communication network). According to an embodiment, the electronic device 1000 may include the processor 1100, the memory 1200, the input module 1300, the display module 1400, a power module 1500, an internal module 1600, and an external module 1700. According to an embodiment, at least one of the above-described components may be omitted from the electronic device 1000, or one or more other components may be added to the electronic device 1000. In an embodiment, some of the components described above (e.g., the sensor module 1610, an antenna module 1620, or the audio output module 1630) may be integrated into another component (e.g., the display module 1400).

The processor 1100 may execute software to control at least one other component (e.g., a hardware or software component) of the electronic device 1000 connected to the processor 1100, and may perform various operations for data processing or computation. According to an embodiment, as at least part of the data processing or computation, the processor 1100 may store a command or data received from another component (e.g., the input module 1300, the sensor module 1610, or a communication module 1730) in a volatile memory 1210, process the command or data stored in the volatile memory 1210, and store resulting data in a non-volatile memory 1220.

The processor 1100 may include a main processor 1110 and an auxiliary processor 1120. The main processor 1110 may include one or more of a central processing unit (CPU) 1111 or an application processor (AP). The main processor 1110 may further include one or more of a graphics processing unit (GPU) 1112, a communication processor (CP), and an image signal processor (ISP). The main processor 1110 may further include a neural processing unit (NPU) 1113. The NPU is a processor specialized in processing an artificial intelligence model, and the artificial intelligence model may be generated through machine learning. The artificial intelligence model may include a plurality of neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof, but is not limited thereto. The artificial intelligence model may additionally or alternatively include a software structure in addition to the hardware structure. At least two of the processing units and processors described above may be implemented as a single integrated configuration (e.g., a single chip) or may be implemented as independent components (e.g., a plurality of chips).

The auxiliary processor 1120 may include a controller 1120-1. The controller 1120-1 may include an interface conversion circuit and a timing control circuit. The controller 1120-1 receives an image signal from the main processor 1110, converts the data format of the image signal to fit the interface specifications with the display module 1400, and outputs image data. The controller 1120-1 may output various control signals necessary for driving the display module 1400.

The auxiliary processor 1120 may further include the controller 1120-1, a data conversion circuit 1120-2, a gamma correction circuit 1120-3, a rendering circuit 1120-4, etc. The data conversion circuit 1120-2 may receive image data from the controller 1120-1, and compensate the image data such that an image is displayed at a desired brightness according to the characteristics of the electronic device 1000 or the user's settings, or convert the image data to reduce power consumption or compensate for an afterimage. The gamma correction circuit 1120-3 may convert image data or a gamma reference voltage, etc. such that an image displayed on the electronic device 1000 has the desired gamma characteristics. The rendering circuit 1120-4 may receive image data from the controller 1120-1 and render the image data by considering the pixel layout of the display panel DP applied to the electronic device 1000. At least one of the data conversion circuit 1120-2, the gamma correction circuit 1120-3, and the rendering circuit 1120-4 may be integrated into another component (e.g., the main processor 1110 or the controller 1120-1). At least one of the data conversion circuit 1120-2, the gamma correction circuit 1120-3, and the rendering circuit 1120-4 may be integrated into a data driver DD to be described below.

The memory 1200 may store various pieces of data used by at least one component of the electronic device 1000 (e.g., the processor 1100 or the sensor module 1610) and input data or output data regarding a command related thereto. The memory 1200 may include at least one of the volatile memory 1210 and the non-volatile memory 1220.

The input module 1300 may receive a command or data to be used for a component of the electronic device 1000 (e.g., the processor 1100, the sensor module 1610, or the audio output module 1630) from the outside of the electronic device 1000 (e.g., a user or the external electronic device 1020).

The input module 1300 may include a first input module 1310 into which a command or data is input from the user, and a second input module 1320 into which a command or data is input from the external electronic device 1020. The first input module 1310 may include a microphone, a mouse, a keyboard, a key (e.g., a button), or a pen (e.g., a passive pen or an active pen). The second input module 1320 may support a designated protocol capable of enabling a wired or wireless connection with the external electronic device 1020. According to an embodiment, the second input module 1320 may include a High-Definition Multimedia Interface (HDMI) unit, a Universal Serial Bus (USB) interface, a Secure Digital (SD) card interface, or an audio interface. The second input module 1320 may include a connector for physically connecting to the external electronic device 1020, for example, an HDMI connector, a USB connector, an SD card connector, or an audio connector (e.g., a headphone connector).

The display module 1400 provides information visually to the user. The display module 1400 may include the display panel DP, a scan driver GP, and the data driver DD. The display module 1400 may further include a window, a chassis, and a bracket to protect the display panel DP.

The display panel DP or the like described with reference to FIG. 15 refers to the display panel DP or the like described above with reference to FIGS. 1 to 14. Thus, redundant descriptions of the display panel DP or the like that are provided above regarding the display panel DP or the like may be omitted.

The display panel DP may further include a light emission driver. The light emission driver outputs a light-emitting control signal to the display panel DP in response to a control signal received from the controller 1120-1. The light emission driver may be implemented separately from the scan driver GP or may be integrated into the scan driver GP.

The scan driver GP receives a control signal from the controller 1120-1, and outputs a scan signal to the display panel DP in response to the control signal. For example, a control signal generated by the controller 1120-1 and delivered to the scan driver GP may be a scan input signal for controlling the scan driver GP. The scan input signal may be an input signal applied to switching elements included in the stages of the scan driver.

The data driver DD receives a control signal from the controller 1120-1, converts image data into analog voltages (e.g., data voltages) in response to the control signal, and then outputs the data voltages to the display panel DP. For example, the control signal generated by the controller 1120-1 and delivered to the data driver DD may be a data input signal for controlling the data driver DD.

The data driver DD may be integrated into another component (e.g., the controller 1120-1). The functions of the interface conversion circuit and the timing control circuit of the controller 1120-1 described above may be integrated into the data driver DD.

The controller 1120-1 may generate a clock signal necessary for driving the scan driver GP. Each stage of the scan driver GP may operate based on a clock signal corresponding to the stage.

The scan driver GP may generate a scan signal based on a scan input signal, a clock signal, and a scan input voltage. The scan signal may be delivered to a pixel circuit, and a thin-film transistor included in the pixel circuit may be driven based on the scan signal. The scan signal may be delivered to a gate included in the pixel circuit.

The display module 1400 may further include a light emission driver, a voltage generation circuit, etc. The voltage generation circuit may output various voltages necessary for driving the display panel DP.

The power module 1500 supplies power to the components of the electronic device 1000. The power module 1500 may generate a gate driving voltage (e.g., a gate high voltage or a gate low voltage) necessary for driving the scan driver GP.

For example, the power module 1500 may refer to a power generation unit, a power supply, etc. For example, the power module 1500 may include a battery to be charged with a power voltage. The battery may include a non-rechargeable primary battery, a rechargeable secondary battery, or a fuel cell.

For example, the power module 1500 may include a power management integrated circuit (PMIC). The PMIC provides optimized power for each of the modules described above and those to be described below.

For example, the power module 1500 may include a wireless power transmission/reception member electrically connected to the battery. The wireless power transmission/reception member may include a plurality of coil-shaped antenna radiators.

The electronic device 1000 may further include the internal module 1600 and the external module 1700. The internal module 1600 may include the sensor module 1610, the antenna module 1620, and the audio output module 1630. The external module 1700 may include the camera module 1710, a light module 1720, and the communication module 1730.

The sensor module 1610 may detect an input by the user's body or an input by a pen included in the first input module 1310, and generate an electric signal or a data value corresponding to the input. The sensor module 1610 may include at least one of the fingerprint sensor 1610-1, an input sensor 1610-2, and a digitizer 1610-3.

The fingerprint sensor 1610-1 may generate a data value corresponding to a fingerprint of the user. The fingerprint sensor 1610-1 may include an optical or capacitive fingerprint sensor.

The input sensor 1610-2 may generate a data value corresponding to coordinate information of an input by the user's body or an input by a pen. The input sensor 1610-2 generates a data value based on an amount of change in electrostatic capacitance caused by the input. The input sensor 1610-2 may detect an input by a passive pen, or transmit and receive data with an active pen.

The input sensor 1610-2 may also measure a biosignal such as blood pressure, moisture, or body fat. For example, when the user touching a sensor layer or a sensing panel with a part of the user's body has not moved for a certain period of time, the input sensor 1610-2 may detect a biosignal based on a change in an electric field caused by the part of the user's body, and output information desired by the user to the display module 1400.

The digitizer 1610-3 may generate a data value corresponding to coordinate information of an input by a pen. The digitizer 1610-3 generates a data value based on an electromagnetic change caused by the input. The digitizer 1610-3 may detect an input by a passive pen, or transmit and receive data with an active pen.

At least one of the fingerprint sensor 1610-1, the input sensor 1610-2, and the digitizer 1610-3 may be implemented as a sensor layer formed on the display panel DP through a continuous process. The fingerprint sensor 1610-1, the input sensor 1610-2, and the digitizer 1610-3 may be arranged on the upper side of the display panel DP, and any one of the fingerprint sensor 1610-1, the input sensor 1610-2, and the digitizer 1610-3, for example, the digitizer 1610-3, may be arranged on the lower side of the display panel DP.

At least two of the fingerprint sensor 1610-1, the input sensor 1610-2, and the digitizer 1610-3 may be formed to be integrated into one sensing panel through the same process. In a case in which they are integrated into one sensing panel, the sensing panel may be arranged between the display panel DP and a window arranged on the upper side of the display panel DP. According to an embodiment, the sensing panel may be arranged on the window, and the location of the sensing panel is not particularly limited.

At least one of the fingerprint sensor 1610-1, the input sensor 1610-2, and the digitizer 1610-3 may be embedded in the display panel DP. That is, at least one of the fingerprint sensor 1610-1, the input sensor 1610-2, and the digitizer 1610-3 may be formed simultaneously through a process of forming elements (e.g., light-emitting elements or transistors) included in the display panel DP.

In addition, the sensor module 1610 may generate an electrical signal or a data value corresponding to an internal state or an external state of the electronic device 1000. The sensor module 1610 may further include, for example, a gesture sensor, a gyro sensor, a barometric sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting or receiving signals or power to or from the outside. According to an embodiment, the communication module 1730 may transmit or receive a signal to or from an external electronic device through an antenna suitable for a communication scheme. An antenna pattern of the antenna module 1620 may be integrated into one component of the display module 1400 (e.g., the display panel DP), or the input sensor 1610-2.

The audio output module 1630 is a device for outputting an audio signal to the outside of the electronic device 1000, and may include, for example, a speaker used for general purposes such as multimedia reproduction or recording reproduction, and a receiver used exclusively for call reception. According to an embodiment, the receiver may be formed integrally with or separately from the speaker. An audio output pattern of the audio output module 1630 may be integrated into the display module 1400.

The camera module 1710 (e.g., a camera device) may capture a still image or a moving image. According to an embodiment, the camera module 1710 may include one or more lenses, image sensors, or ISPs. The camera module 1710 may further include an IR camera capable of measuring the presence or absence of a user, the user's location, the user's gaze, etc. For example, the camera module 1710 may be used to capture images of the above-described pads; the processors 1100 or 1120 may determine the virtual lines VL1 and VL2, the distance therebetween, and whether they are aligned or need to be adjusted based on the distance. The electronic device 1000 may additionally include actuators (e.g., linear actuators), robotic arms or motorized stages that may be used to adjust positions of the pads (PP and/or FP) or the positions of the substrates on which the pads are located, to ensure a proper connection between the panel pads PP and the connection pads FP and between the panel pads PP and the additional pads AP1/AP2.

The light module 1720 may provide light. The light module 1720 may include a light-emitting diode or a xenon lamp. The light module 1720 may operate in conjunction with the camera module 1710 or independently.

The communication module 1730 may support establishment of a wired or wireless communication channel between the electronic device 1000 and the external electronic device 1020, and execution of communication through the established communication channel. The communication module 1730 may include any one of or both a wireless communication module such as a cellular communication module, a short-range wireless communication module, or a global navigation satellite system (GNSS) communication module, and a wired communication module, such as a local area network (LAN) communication module, or a power line communication module. The communication module 1730 may communicate with the external electronic device 1020 via a short-range communication network such as Bluetooth, Wi-Fi direct, or Infrared Data Association (IrDA), or via a long-range communication network such as a cellular network, the Internet, or a computer network (e.g., a LAN or a wide area network (WAN)). Various types of communication modules described above may be implemented as a single chip or as separate chips.

The input module 1300, the sensor module 1610, the camera module 1710, and the like may be used to control the operation of the display module 1400 in conjunction with the processor 1100.

The processor 1100 outputs a command or data to the display module 1400, the audio output module 1630, the camera module 1710, or the light module 1720, based on input data received from the input module 1300. For example, the processor 1100 may generate image data in response to input data received through a mouse or an active pen, and output the image data to the display module 1400, or generate command data in response to the input data and output the image data to the camera module 1710 or the light module 1720. When no input data is received from the input module 1300 for a certain period of time, the processor 1100 may switch the operation mode of the electronic device 1000 to a low-power mode or a sleep mode to reduce the power consumption of the electronic device 1000.

The processor 1100 outputs a command or data to the display module 1400, the audio output module 1630, the camera module 1710, or the light module 1720, based on sensing data received from the sensor module 1610. For example, the processor 1100 may compare authentication data applied from the fingerprint sensor 1610-1 with authentication data stored in the memory 1200, and then execute an application based on a result of the comparison. The processor 1100 may execute a command or output corresponding image data to the display module 1400, based on sensing data detected by the input sensor 1610-2 or the digitizer 1610-3. In a case in which a temperature sensor is included in the sensor module 1610, the processor (1100) may receive temperature data regarding a measured temperature from the sensor module 1610, and perform brightness correction or the like on the image data based on the temperature data.

The processor 1100 may receive, from the camera module 1710, measurement data regarding the presence or absence of a user, the user's location, the user's gaze, etc. The processor 1100 may further perform brightness correction or the like on the image data based on the measurement data. For example, the processor 1100 that has determined the presence or absence of the user through an input from the camera module 1710 may output image data of which the brightness has been corrected through the data conversion circuit 1120-2 or the gamma correction circuit 1120-3, to the display module 1400.

Some of the components described above may be connected to each other by using a communication scheme between peripheral devices, for example, a bus, a general-purpose input/output (GPIO), a serial peripheral interface (SPI), a mobile industry processor interface (MIPI), or an ultra path interconnect (UPI) link, to exchange signals (e.g., commands or data) with each other. The processor 1100 may communicate with the display module 1400 through an interface that is pre-agreed therebetween, and for example, may use any of the above-described communication schemes, and is not limited to the above-described communication schemes.

The electronic device 1000 according to various embodiments disclosed herein may include various types of devices. The electronic device 1000 may include, for example, at least one of a portable communication device (e.g., a smart phone), a computer device, a portable multimedia device, a portable medical device, a camera, a wearable device, or a home appliance. The electronic device 1000 according to an embodiment of the present disclosure is not limited to the above devices.

In an embodiment, the electronic device may include the controller 1120-1, a power module, and a display module. The display module may include a display panel and the scan driver GP. The controller 1120-1 may generate a scan input signal necessary for driving the scan driver GP. The power module may generate a scan input voltage necessary for driving the scan driver GP, under control of the processor or the controller 1120-1. For example, the scan input voltage may be a gate driving voltage.

The display panel DP may be partitioned into the display area DA in which pixel circuits are arranged, and the non-display area NDA surrounding the display area DA. As described above, an area where an image is displayed may correspond to the display area DA, and an area outside the display area DA where no image is displayed may correspond to the non-display area NDA.

The scan driver GP may be arranged in a peripheral area and may receive a scan input signal from the controller 1120-1 and a scan input voltage from the power module. The scan driver GP may generate a scan signal or output a scan signal based on a scan input signal and/or a scan input voltage. The scan signal may be delivered from the scan driver GP to the pixel circuit.

In an embodiment, the scan driver GP may include at least one capacitor. The at least one capacitor may include one electrode and another electrode. For example, the one electrode may be a signal line that delivers at least one of a scan input signal or a scan input voltage. For example, the one electrode may be at least a portion of a signal line that delivers at least one of a scan input signal or a scan input voltage. The signal line may be, for example, a wire through which a scan input voltage is delivered.

For example, the other electrode may overlap with the one electrode. The other electrode may overlap with a signal line that delivers at least one of a scan input signal or a scan input voltage. For example, the other electrode may overlap with at least a portion of a signal line that delivers at least one of a scan input signal or a scan input voltage.

In an embodiment, the non-display area NDA may include a wire arrangement area in which wires are arranged, and a circuit arrangement area in which at least one transistor is arranged between the display area DA and the wire arrangement area. For example, at least one capacitor may be arranged in the wire arrangement area. At least one capacitor may be arranged in the wire arrangement area.

In an embodiment, on a plan view, the at least one capacitor may be spaced apart from the at least one transistor in a first direction, and the signal line may extend in a second direction intersecting the first direction.

In addition, the display module included in the electronic device may include the features of the display panel DP described above with reference to FIGS. 1 to 14. Those skilled in the art would readily understand that the description of the display panel DP provided above with reference to FIGS. 1 to 14 may be applied to the display module of FIG. 15.

Each of the embodiments described above may be implemented independently, but the structure of each embodiment may be applied to other embodiments in combination.

Although the present disclosure has been described with reference to the embodiment shown in the drawings, which is merely exemplary, it will be understood by those skilled in the art that various modifications and equivalent other embodiments are possible therefrom.

The particular implementations shown and described herein are illustrative examples of the embodiments and are not intended to otherwise limit the scope of the embodiments in any way.

According to an embodiment of the present disclosure, a display device, an electronic device including the display device, and a method of manufacturing the display device may be implemented, in which alignment measurement is facilitated by additionally connecting additional pads of a display panel to connection pads of a connection circuit board, electrical coupling is stably performed, and high-resolution images may be implemented.

What is claimed is:

1. A display device including a display panel, the display panel comprising:
a display area including a plurality of pixels;
a non-display area including a panel pad group comprising a plurality of panel pads arranged in a first direction and connected to one of the pixels to receive one or more signals,
wherein the panel pad group further comprises an additional pad portion arranged in a lengthwise direction of each of the plurality of panel pads and spaced apart from the panel pads, and
wherein the additional pad portion comprises a first additional pad and a second additional pad that are sequentially spaced apart from one another in the lengthwise direction of the panel pads.

2. The display device of claim 1, wherein the first additional pad and the second additional pad overlap with an extension line that passes through centers of the panel pads in a widthwise direction of the panel pads, and extends in the lengthwise direction of the panel pads.

3. The display device of claim 1, wherein the first additional pad and the second additional pad are arranged parallel to each other.

4. The display device of claim 1, wherein the panel pads and the additional pad portion are arranged parallel to each other.

5. The display device of claim 1, wherein the second additional pad is arranged closer to the display area in the lengthwise direction of the panel pads than the first additional pad.

6. The display device of claim 1, wherein at least two of the plurality of panel pads are inclined and are not parallel to each other.

7. The display device of claim 1, wherein a width of one end of the panel pad group that is closest to the display area is greater than a width of another end of the panel pad group that is closest to an edge of the display panel.

8. The display device of claim 1, wherein a width of the panel pad group in the first direction gradually decreases away from the display area.

9. The display device of claim 1, wherein centers of the panel pads, the first additional pad, and the second additional pad are all positioned on a straight line.

10. The display device of claim 1, further comprising a connection circuit board comprising a connection pad group comprising a plurality of connection pads that are arranged in the first direction on the connection circuit board,
wherein the connection circuit board is configured to deliver the signals to the panel pad group.

11. The display device of claim 10, wherein each of the plurality of connection pads is arranged to overlap with at least one area of each of the panel pad, the first additional pad, and the second additional pad.

12. The display device of claim 10, wherein the plurality of connection pads of the connection pad group correspond to and electrically connect to the plurality of panel pads of the panel pad group, respectively.

13. The display device of claim 10, wherein the connection circuit board comprises a plurality of connection circuit boards that are arranged in the first direction.

14. The display device of claim 13, wherein the panel pad group comprises a plurality of panel pad groups that are arranged to correspond to the plurality of connection circuit boards, and
the plurality of panel pad groups correspond to and electrically connect to the plurality of connection circuit boards, respectively.

15. The display device of claim 1, further comprising a third additional pad arranged between the first additional pad and the second additional pad.

16. A method of manufacturing a display device, the method comprising:
forming a display panel comprising a display area including a plurality of pixels and non-display area including a panel pad group, the panel pad group comprising a plurality of panel pads aligned in a first direction, and an additional pad portion positioned spaced apart from the panel pads on a straight line extending in a lengthwise direction of each of the plurality of panel pads;
forming a connection circuit board comprising a connection pad group comprising a plurality of connection pads aligned in the first direction; and
connecting the display panel to the connection circuit board such that one of the connection pads overlaps with one of the panel pads and the additional pad portion.

17. The method of claim 16, wherein the additional pad portion comprises a first additional pad and a second additional pad that are sequentially spaced in a straight line extending in the lengthwise direction of the panel pads, and
the connecting of the display panel to the connection circuit board comprises causing each of the plurality of connection pads to overlap with and connect to at least one of the panel pads, the first additional pad, and the second additional pad.

18. The method of claim 17, further comprising, before the connecting of the display panel to the connection circuit board, inspecting alignment of the panel pad group and the connection pad group.

19. The method of claim 18, wherein the inspecting of the alignment of the panel pad group and the connection pad group comprises generating a first virtual line connecting centers of the first additional pad and the second additional pad, and then measuring a difference between the first virtual line and a second virtual line connecting centers of the connection pads.

20. An electronic device comprising:
a controller configured to generate a scan input signal;
a power module configured to generate a scan input voltage;
a display panel including a display area comprising pixel circuits, and a non-display area surrounding the display area; and
a scan driver arranged in the non-display area and configured to receive the scan input signal and the scan input voltage and output a scan signal to the pixel circuits,
wherein the non-display area includes a panel pad group, the panel pad group comprising a plurality of panel pads arranged in a first direction and connected to one of the pixel circuits,
wherein the panel pad group further comprises an additional pad portion arranged in a lengthwise direction of each of the plurality of panel pads and spaced apart from the panel pads, and
wherein the additional pad portion comprises a first additional pad and a second additional pad that are sequentially spaced in the lengthwise direction of the panel pads.
